(19) United States
(12) Patent Application Publication
(10) Pub. No.: US 2025/0096003 A1
(43) Pub. Date: Mar. 20, 2025

(54) METHOD FOR PRODUCING A STRUCTURE COMPRISING AT LEAST TWO TILES ON A SUBSTRATE

(71) Applicant: Soitec, BERNIN (FR)

(72) Inventor: Bruno Ghyselen, BERNIN (FR)

(21) Appl. No.: 18/729,324

(22) PCT Filed: Jan. 17, 2023
(86) PCT No.: PCT/FR2023/050061

§ 371 Date: Jul. 16, 2024

(30) Foreign Application Priority Data
Jan. 17, 2022 (FR) FR2200361

(51) Int. Cl. H01L 21/308; C30B 33/08

(52) U.S. Cl. CPC H01L 21/308; C30B 33/08

(57) ABSTRACT

A method of manufacturing a structure comprising at least two tiles on a substrate comprises: —placing, on a support substrate, at least two tiles, the tiles being arranged on the support substrate in an incorrect distribution and/or geometry compared with a target distribution and/or geometry; —forming a mask comprising a protective film partially covering the tiles in a pattern defining the target distribution and/or geometry and at least one opening extending around the protective film; and —etching at least one tile through the opening in the mask so as to correct the arrangement of the tiles according to the target distribution and/or geometry.

### CROSS REFERENCE TO RELATED APPLICATIONS

This application is a national phase entry under 35 U.S.C. § 371 of International Patent Application PCT/FR2023/050061, filed Jan. 17, 2023, designating the United States of America and published as International Patent Publication WO 2023/135401 A1 on Jul. 20, 2023, which claims the benefit under Article 8 of the Patent Cooperation Treaty to French Patent Application Serial No. FR2200361, filed Jan. 17, 2022.

### TECHNICAL FIELD

The present disclosure relates to a process for manufacturing a structure comprising at least two tiles on a support substrate.

### BACKGROUND

In the field of microelectronics, optics or optoelectronics, the design of multilayer structures sometimes requires tiles, in the form of portions of a layer of a donor substrate, to be transferred to a support substrate or receiver substrate.

This type of process is generally referred to as a tiling process, and involves partial transfer of a layer taken from the donor substrate to form one or more tiles arranged in a pattern or at a predetermined position on the support substrate.

Such tiling may be made necessary by a difference in size between the donor substrate and the support substrate. Specifically, on account of this difference in size, it is not possible to transfer an entire layer of the donor substrate to the support substrate.

A well-known layer transfer process is the Smart Cut™ process, in which, by implanting atomic species in the donor substrate, a weakened zone delimiting the layer to be transferred is formed, the donor substrate is bonded to the support substrate and the donor substrate is detached along the weakened zone in order to transfer the layer from the donor substrate to the support substrate. However, that process assumes that the donor substrate and the support substrate are the same size.

But, while silicon substrates with a relatively large size, typically a diameter of 300 mm, are available, other materials of interest currently only exist in the form of bulk substrates of smaller size, for example, with a diameter of 10 or 15 cm. Furthermore, these materials of interest are sometimes particularly expensive, and so it is desirable to minimize the potential waste formed during the transfer. Such is the case, in particular, for the semiconductor materials III-V, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AIP)).

Rather than transferring an entire layer of the donor substrate, a solution based on the Smart Cut™ process consists in taking from at least one donor substrate one or more tiles and transferring the tiles to a first substrate to form what is known as a pseudo-donor substrate, forming, by implanting atomic species, a weakened zone in each tile, bonding the pseudo-donor substrate to a second substrate via the tiles, and detaching each tile along the weakened zone so as to transfer a portion of each tile to the second substrate. The first and second substrates are the same size.

FIG. 1 shows a top view and a cross-sectional view of a support substrate S on which a plurality of tiles P1-P9 from at least one donor substrate have been disposed. In this example, there are nine tiles, which are distributed in three rows and three columns.

The structure can be manufactured using the “pick and place” technique, in which the at least one donor substrate is cut into tiles and then each tile is placed on the surface of the support substrate with the aid of a robot.

However, since each tile is transferred individually to the first substrate, this technique can be very slow, especially since the precision required for aligning the tiles is demanding. The precision of the robot may furthermore be lower than the precision required for placing and orienting the tiles. Therefore, tile positioning errors are observed with respect to a reference frame of the support substrate, and/or tile alignment errors with one another.

Examples of such errors are illustrated in FIGS. 2A and 2B, which show four tiles P1-P4 arranged in two rows (oriented along the horizontal direction in these figures) and two columns (oriented along the vertical direction in these figures). In FIG. 2A, it can be seen that the tile P4 is offset by a distance d₁ in the vertical direction with respect to the tile P3, which belongs to the adjacent column, and by a distance d₂ in the horizontal direction with respect to the tile P2, which belongs to the same column. In FIG. 2B, it can be seen that the tile P4 is inclined at an angle α with respect to the vertical direction, such that its edges are not parallel to those of the adjacent tiles.

These alignment or positioning errors are problematic for the subsequent manufacture of electronic components in or on the tiles, which need to comply with a particularly precise plan.

Furthermore, as illustrated in FIG. 2C, during the layer transfer operation or when a plurality of transfers are carried out in succession from the pseudo-donor substrate, an edge effect phenomenon may be observed, which impairs the shape of the edges of the tiles P1-P4 and is therefore likely to affect the subsequent manufacture of components in or on the tiles, in particular, in the vicinity of the edges.

### BRIEF SUMMARY

An aim of the present disclosure is to design a process for manufacturing a structure comprising at least two tiles on a support substrate, which makes it possible to reduce the tile positioning and alignment errors.

To this end, the present disclosure proposes a process for manufacturing a structure comprising at least two tiles on a substrate, comprising:
placing, on a support substrate, at least two tiles, the tiles being arranged on the support substrate in an incorrect distribution and/or geometry compared with a target distribution and/or geometry;
forming a mask comprising a protective film partially covering the tiles in a pattern defining the target distribution and/or geometry and at least one opening extending around the protective film;
etching at least one tile through the opening in the mask so as to correct the arrangement of the tiles according to the target distribution and/or geometry.

The term “etching” means, in the present disclosure, a chemical and/or physical attack on the material of the tiles, causing elimination of the zone of the tiles that is not covered by the protective film.

The mask is positioned using a very precise technique with respect to a reference frame of the set of tiles, or with respect to a reference frame of the support substrate over which the tiles extend, such that the tiles that are obtained following etching are positioned and/or shaped precisely.

A “reference frame” means, in the present disclosure, a system of coordinates associated with a substrate bearing the tiles, or with the set of tiles, and that makes it possible to define the position of each point of the surface of the substrate or of the set of tiles.

For example, the reference frame may comprise a datum point that is able to be located on an edge of the substrate, such as a notch conventionally used in the semiconductor industry, and two orthogonal axes extending in the plane of the substrate, one of the axes extending diametrically from the notch and the other axis intersecting the first axis at the center of the substrate. Such a reference frame is used to define the position of the components to be formed in or on the substrate and to localize the different steps of the process to be implemented to form the components.

Alternatively, it is possible for the reference frame not to be defined with respect to the support substrate but with respect to the set of tiles. For example, the reference frame may be defined by one or more marks formed on at least one of the tiles and/or on the support substrate.

In certain embodiments, the tiles are placed successively on the support substrate.

In other embodiments, the tiles are placed simultaneously on the support substrate.

In particular, the process may comprise:
forming a pseudo-donor substrate by placing each tile of at least one donor substrate on a first support substrate;
bonding the pseudo-donor substrate to a second support substrate via the tiles;
transferring a portion of the tiles to the second support substrate.

In certain embodiments, the first and the second support substrate have identical diameters, greater than the diameter of the donor substrate.

Particularly advantageously, the pseudo-donor substrate may be bonded to the second support substrate by molecular adhesion.

The transfer of each tile portion may comprise, in succession, forming a weakened zone by implanting atomic species in each tile placed on the pseudo-donor substrate in order to define a portion to be transferred, bonding the pseudo-donor substrate to the second support substrate via the tiles, and detaching each tile along the weakened zone.

Each tile may typically have a thickness of between 20 μm and 1000 μm, preferably between 100 μm and 700 μm, and the transferred portion of each tile may have a thickness of between 30 nm and 1.5 μm.

The formation of the mask and the etching may be carried out after each tile portion has been transferred to the second support substrate. Alternatively or additionally, the formation of the mask and the etching may be carried out on the tiles of the pseudo-donor substrate prior to bonding to the second support substrate.

In certain embodiments, each tile has a side with a length less than or equal to 10 mm, preferably less than or equal to 5 mm, and more preferably less than or equal to 2 mm.

In other embodiments, each tile has a side with a length greater than or equal to 3 mm, preferably greater than or equal to 5 mm, and more preferably greater than or equal to 8 mm.

The protective film may advantageously cover each tile in at least two patterns separated by openings, and the etching of the tile through the openings in the mask then forms at least two portions of tiles in the patterns from the tile.

Particularly advantageously, each tile may comprise:
a semiconductor material, such as a III-V material, in particular, indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP) or aluminum phosphide (AIP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN), and/or
an electrically insulating material, such as diamond, strontium titanate, yttria-stabilized zirconia or sapphire.

In certain embodiments, the process comprises forming at least one epitaxial layer on each tile, the formation of the mask and the etching being carried out after the epitaxy step.

### BRIEF DESCRIPTION OF THE DRAWINGS

Further features and advantages of the present disclosure will become apparent from the following detailed description, with reference to the appended drawings, in which:

FIG. 1 shows a top view and a cross-sectional view of a support substrate on which a plurality of tiles from a donor substrate have been disposed;

FIGS. 2A to 2C show top views of three examples of alignment or geometry errors of the tiles on a support substrate of the type illustrated in FIG. 1;

FIG. 3 illustrates a particular embodiment of a pseudo-donor substrate;

FIGS. 4A to 4E respectively illustrate steps of taking tiles from a donor substrate, of placing the tiles on a first support substrate to form a pseudo-donor substrate, of forming a weakened zone in the tiles, of bonding the pseudo-donor substrate to a second support substrate via the tiles and of transferring the portions of the tiles to the second support substrate following the detachment of the tiles along the weakened zone;

FIG. 5 shows a top view and a cross-sectional view of a support substrate covered with tiles;

FIG. 6 shows a top view and a cross-sectional view of the structure in FIG. 5 after the formation of a mask on the tiles by photolithography, according to a first embodiment of the present disclosure;

FIG. 7 shows a top view and a cross-sectional view of the structure in FIG. 6 after the etching of the regions of the tiles that are not covered by the mask;

FIG. 8 shows a top view and a cross-sectional view of the structure in FIG. 7 after removal of the mask;

FIGS. 9A to 9C schematically illustrate how the alignment or geometry errors shown in FIGS. 2A to 2C have been corrected by virtue of the present disclosure;

FIG. 10 shows a top view and a cross-sectional view of a support substrate covered with tiles with a larger dimension than in the embodiment in FIG. 5;

FIG. 11 shows a top view and a cross-sectional view of the structure in FIG. 10 after the formation of a mask on the tiles by photolithography, according to a second embodiment of the present disclosure;

FIG. 12 shows a top view and a cross-sectional view of the structure in FIG. 11 after the etching of the regions of the tiles that are not covered by the mask;

FIG. 13 shows a top view and a cross-sectional view of the structure in FIG. 12 after removal of the mask; and

FIGS. 14A to 14D illustrate a third embodiment of the present disclosure, in which, after the tiles have been placed on a support substrate, an epitaxial layer is grown on each tile and then the mask, as defined above, is applied to the epitaxial layer, and both the epitaxial layer and the tiles are etched in order to correct the geometry and/or the distribution of the tiles.

For the sake of legibility, the drawings have not necessarily been drawn to scale. Furthermore, the number of tiles schematically shown in the drawings is given only by way of illustration.

### DETAILED DESCRIPTION

The present disclosure proposes correcting distribution and/or geometry errors of tiles placed on a support substrate, to achieve a target distribution and/or geometry.

The target distribution and/or geometry may be specified, for example, by a manufacturer of devices for microelectronics, optics or optoelectronics. Specifically, the manufacture of such devices in or on each tile involves using localized techniques that require a precise location and shape for each tile.

To this end, after at least two tiles have been placed on the support substrate, a mask comprising a protective film partially covering the tiles is formed. The mask also comprises at least one opening around the film. Each opening forms an access point for an etchant, the composition of which is chosen to chemically and/or physically attack the material of the tile. The protective film is made of a material that is resistant to the etchant and therefore protects the material of the tile from the etchant in the zones covered by the protective film. Thus, the application of the etchant etches the material of the tile only in the zones that are not covered by the protective film, thereby making it possible to modify the geometry of the tiles. This correction of the geometry at the scale of each tile also makes it possible to correct the distribution or the alignment of the tiles with respect to one another.

Particularly advantageously, the mask is formed by photolithography, the protective film then being formed from a photosensitive resin that resists the etchant, which is a chemical etching composition. Since photolithography is generally more precise than the processes for placing the tiles, it therefore makes it possible to ensure that the tile zones protected by the protective film conform to the target distribution and/or geometry.

Alternatively, the etchant is an ion beam (technique known as “sputtering”) and the mask comprises a metal protective film that protects the material of the tiles from the ion beam in the zones covered by the protective film.

The mask is removed after the tiles have been etched over all or part of their thickness.

It will be noted that it is possible to do away with the use of a mask if use is made of a selective etching process employing a controlled focused etching ion beam for only sweeping over the zones of the tiles that are to be eliminated.

This process can be implemented in different steps of a tiling process.

Thus, the process can be implemented after tiles have been placed on a first support substrate from one or more donor substrates.

The first support substrate may be a final support or a temporary support.

Furthermore, the tiles may be placed successively tile by tile or simultaneously for the set of tiles.

Thus, for example, the first support substrate covered with tiles may be a pseudo-donor substrate, intended for subsequently transferring the tiles to a second support substrate, which may be a final support or a new temporary support.

In this case, the tiles can be placed on the first support substrate tile by tile, for example, using the “Pick and Place” process; on the other hand, the tiles can be transferred from the pseudo-donor substrate to the second support substrate simultaneously.

The process for correcting the distribution and/or geometry of the tiles may be carried out after the tiles have been placed on the first support substrate and/or after the tiles have been transferred to the second support substrate. Preferably, the process is carried out after the tiles have been transferred to the second support substrate, in order to correct any edge effects associated with the layer transfer step.

In certain embodiments, the number of tiles remains the same before and after the process is carried out. Such is the case, in particular, when the tiles have relatively small dimensions, the etching mainly being carried out at the periphery of each tile. For example, each tile initially has a side with a length less than or equal to 10 mm, preferably less than or equal to 5 mm, and more preferably less than or equal to 2 mm.

In other embodiments, the process makes it possible to subdivide a tile into several smaller tiles. The process thus has the advantage of forming tiles with very small dimensions without it being necessary to place them individually on the support substrate, the etching of the tiles from larger tiles being quicker than placing each of the small tiles. For example, each tile initially has a side with a length greater than or equal to 3 mm, preferably greater than or equal to 5 mm, and preferably greater than or equal to 8 mm.

Advantageously, the tiles are made of a material that is not commercially available in the form of a donor substrate with large dimensions. Thus, the donor substrate may have a diameter less than 30 cm, for example, around 10 or 15 cm.

Such is the case, in particular, for the semiconductor materials III-V, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AIP)).

This is also the case for semiconductor IV or IV-IV compounds, for example, germanium and silicon carbide.

The tiles may also be made of a piezoelectric material, for example, lithium tantalate (LiTaO₃) or lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and of lead titanate (PMN-PT), zinc oxide (ZnO), aluminum nitride (AlN) or aluminum-scandium nitride (AlScN) (non-limiting list).

The tiles may also be made of an electrically insulating material, for example, diamond, strontium titanate (SrTiO₃), yttria-stabilized zirconia (YSZ) or sapphire.

Given the difference in size between the donor substrate and the support substrate, several donor substrates may be necessary to tile the entire surface of the support substrate depending on the desired tiling density.

It will be noted that the tiles do not necessarily stand proud on the support substrate. For example, the tiles may be placed in cavities formed in the main surface of the support substrate, the upper surface of the tiles lying flush with the surface of the support substrate or being situated above or below this surface.

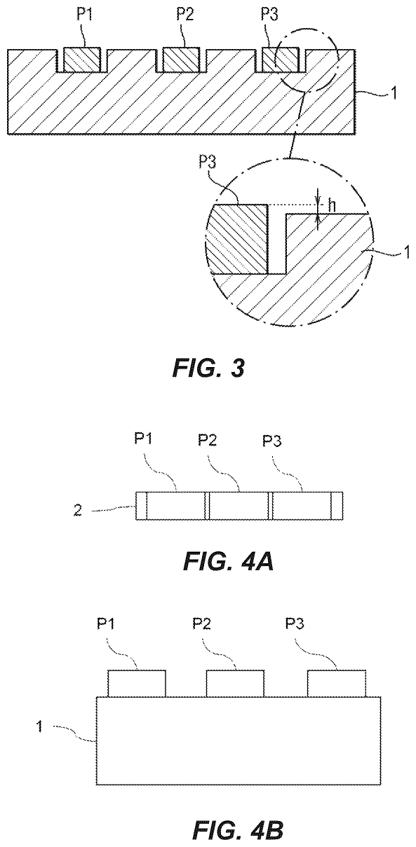

FIG. 3 is a schematic cross-sectional view of a pseudo-donor substrate according to one particular embodiment. The substrate comprises tiles P1, P2, P3 and a first support substrate 1. Each tile is arranged in a respective cavity of the substrate 1 formed in the main surface of the substrate 1, such that the free surface of the tiles is substantially aligned (coplanar) with the surface of the substrate 1.

As can be seen better in the insert, which depicts an enlarged view of the tile P3 in its cavity, the free surface of each tile is situated at a height h with respect to the surface of the substrate 1. The height h may be zero (the free surface of the tiles and the main surface of the substrate being coplanar), positive (the tiles then being slightly proud with respect to the main surface of the substrate) or negative (the tiles then being slightly set back with respect to the main surface of the substrate). In terms of absolute value, the height h is typically between 1 and 10% of the total thickness of the transferred portion of the tiles. Furthermore, the height h may preferably be between several tenths of μm and several tens of μm.

Advantageously, the proud embodiment, in other words when the height h is positive, is the preferred embodiment when the pseudo-donor is configured to be bonded to a planar support substrate. Furthermore, a pseudo-donor with set-back tiles (the height h is negative) may be bonded to a support substrate provided with a surface comprising a topology configured to compensate the topology of the pseudo-donor substrate such that the set-back tiles are in contact with the surface of the support substrate.

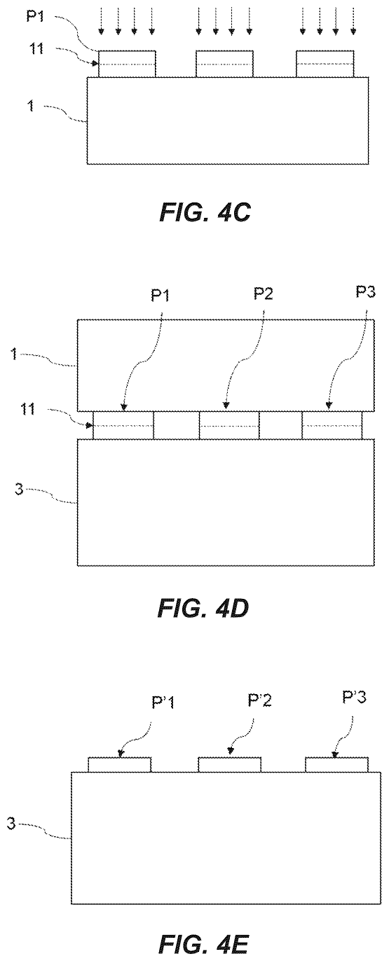

FIGS. 4A to 4E schematically illustrate the formation of a pseudo-donor substrate comprising the tiles placed on a first support substrate and the transfer of the tiles to a second support substrate.

With reference to FIG. 4A, tiles P1-P3 are cut from a donor substrate 2. The tiles can be cut using any technique known to those skilled in the art. It may, in particular, be carried out by sawing and/or cleavage, or by laser cutting. It may also, for example, be combined with a step of partial plasma etching the cutting lines, a technique also known as “plasma dicing.”

FIG. 4B illustrates the placing of the tiles taken from the donor substrate in FIG. 4A on a first support substrate 1 in order to form a pseudo-donor substrate.

Placing may also be carried out using the “Pick and Place” technique, in which a robot takes hold of a tile previously cut from the donor substrate and places it at a predetermined location on the first support substrate.

In certain embodiments, each tile adheres to the first support substrate by molecular adhesion. To this end, surface treatments of the tiles and/or of the first support substrate may be carried out beforehand in order to promote good molecular adhesion. These treatments may comprise, in particular, cleaning, the deposition of a bonding layer such as a silicon oxide (SiO₂), plasma activation before bonding, and annealing.

In other embodiments, the bonding of the tiles to the first support substrate may involve an intermediate bonding layer, for example, a polymer bonding layer, a eutectic bonding layer or a ceramic bonding layer.

The first support substrate 1 advantageously has a diameter greater than that of the donor substrate 2, for example, a diameter of around 300 mm.

FIG. 4C illustrates the formation of a weakened zone in the tiles P1-P3 in order to delimit a surface portion of the tiles that is intended to be transferred to a second support substrate. As schematically indicated by the arrows, the weakened zone 11 is advantageously formed by the implantation of atomic species, such as hydrogen and/or helium, in the tiles, at a depth corresponding to the thickness of the layer to be transferred.

FIG. 4D illustrates the bonding of the pseudo-donor substrate in FIG. 4C to a second support substrate via the tiles.

Particularly advantageously, each tile adheres to the second support substrate 3 by molecular adhesion. To this end, surface treatments of the tiles and/or of the second support substrate may be carried out beforehand in order to promote good molecular adhesion. These treatments may comprise, in particular, cleaning, the deposition of a bonding layer such as a silicon oxide (SiO₂), plasma activation before bonding, polishing and annealing, preferably at low temperature (meaning typically below 300° C.).

The first support substrate 1 and the second support substrate 3 have the same diameter, for example, around 300 mm.

Next, with reference to FIG. 4E, the tiles are detached along the weakened zone 11 in order to transfer the portions P′1, P′2, P′3 delimited by the weakened zone to the second support substrate.

The tiles placed on the first support substrate typically have a thickness of between 20 μm and 1000 μm, preferably between 100 μm and 700 μm. The transferred portion of each tile generally has a thickness of between 30 nm and 1.5 μm.

The process according to the present disclosure may be carried out on the pseudo-donor substrate in FIG. 4B or 4C and/or on the final structure in FIG. 4E.

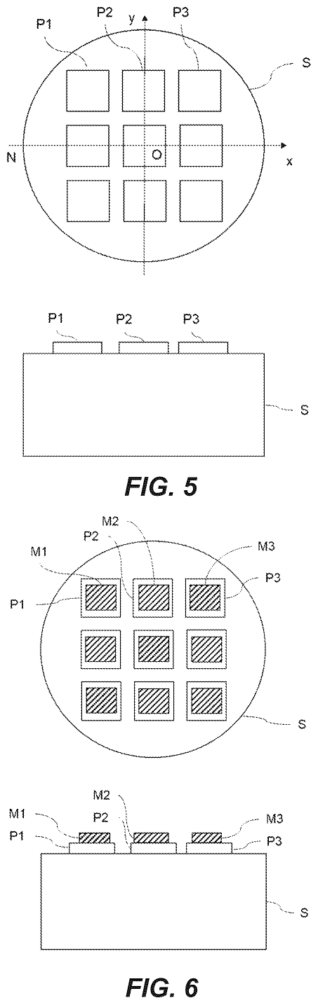

The steps of the process are illustrated schematically in FIGS. 5 to 8. These figures show tiles P1-P3 and a support substrate S, but it goes without saying that, depending on the structure to which the process is applied, the tiles P1-P3 may be replaced by the portions of tiles P′1-P′3 as illustrated in FIG. 4E, and the support substrate S may be the first support substrate 1 in FIG. 4B or 4C or the second support substrate 3 in FIG. 4E.

FIG. 5 illustrates a support substrate S on which a plurality of tiles P1-P3 have been placed. Given the technique of cutting and/or placing the tiles, the tiles may have an incorrect geometry compared with a target geometry, and/or an incorrect distribution compared with a target distribution. The target geometry may be characterized typically by a shape of the tiles in top view (top of FIG. 5) and/or by dimensions of the tiles. The target distribution may be characterized by an alignment of the tiles with respect to one another, a distance between adjacent tiles, and/or a location of each tile in a system of coordinates of the substrate S or a system of coordinates of the set of tiles.

Different frames of reference of the substrate and/or of the tiles may be defined with respect to locating marks (for example, in the form of crosses) provided:
on the support substrate before the placing of the tiles or the transfer of the tiles, outside of the tiles, and
on the tiles after they have been placed on or transferred to the support substrate, in particular, at the time of the etching of a chosen tile (for example: the first tile placed in the case of placing using the “Pick and Place” technique, or a transferred tile chosen depending on its location or the quality of its transfer in the case of simultaneous transfer of tiles to the support substrate).

In example of a system of coordinates (O, x, y) of the substrate S is schematically shown in FIG. 5. In this example, the point O is the center of the substrate S. The axis (Ox) passes through a notch N that already exists at the edge of the substrate S. The axis (Oy) is perpendicular to the axis (Ox). Of course, other systems of coordinates may be used without departing from the scope of the present disclosure.

FIG. 6 illustrates the formation, for example, by photolithography, of a mask comprising a protective film M1-M3 partially covering each tile P1-P3 and openings extending between the portions of the protective film.

The protective film defines a pattern corresponding to the target geometry and/or distribution of the tiles.

The film may be made from any appropriate resin. In particular, in the field of microelectronics, such photosensitive resins, sold, for example, by the companies Shipley or AZ Electronic Materials, are dispensed in a viscous state and spread over the substrates with the aid of spinners (known as a “spin coating” operation), then annealed. A UV irradiation step makes it possible, after they have been revealed, to retain or conversely to eliminate the exposed zones. According to a variant known as “dry film photoresist,” these resins may also be applied by lamination of a thick film, with a thickness typically of between 15 and 50 μm, supplied in the form of rolls.

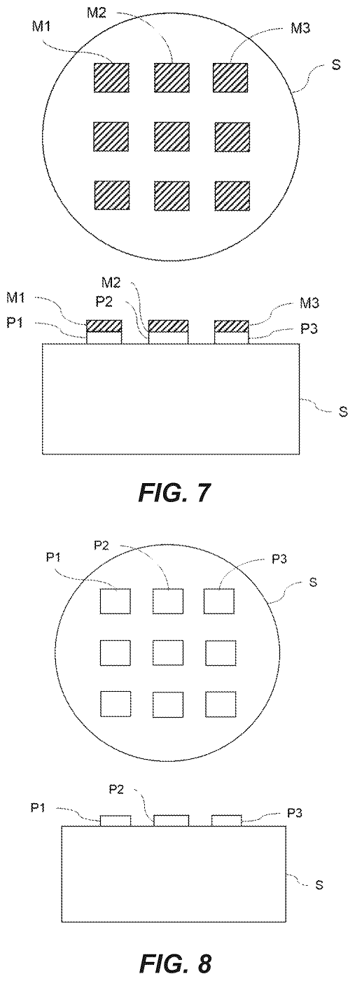

With reference to FIG. 7, an etching solution is applied to the structure in FIG. 6. The composition of the etching solution is chosen depending on the material of the tiles. For example, when the tiles are made of InP, use could be made of wet etching in a bath of hydrochloric acid (HCl) and phosphoric acid (H₃PO₄). Use could also be made of plasma etching based on halogenated gases (based on chlorine, for example, or on methane/dihydrogen (CH₄/H₂) mixtures).

Advantageously, the etching solution does not attack, or hardly attacks, the material of the substrate S.

Alternatively, etching by, for example, argon, ion-beam sputtering may also be used. In this case, the protective film is advantageously metallic.

At the end of etching, the peripheral part of the tiles that is not covered with the protective film has been removed, over all or part of the thickness of the tiles. In certain embodiments, in particular, when the process is carried out on the pseudo-donor substrate before the tiles are transferred to another substrate, it may be sufficient to etch the tiles over only a part of their thickness. This etched part may typically have a thickness greater than or equal to the thickness to be transferred, or greater than or equal to a multiple of the thickness to be transferred when the pseudo-donor substrate needs to be used several times for transferring tiles. Purely by way of indication, the thickness of the etched part may thus be several tens of micrometers. In other situations, in particular, when the process is carried out after the tiles have been transferred, for example, to the final substrate, it may be preferable to etch the tiles over their entire thickness.

Therefore, there are, on the support substrate S, tiles of which the geometry and/or distribution are in concordance with the target geometry and/or distribution.

Optionally, the etching step may be exploited to form, on the support substrate and/or on one or more tiles, one or more locating marks intended to make it easier to localize the different tiles for subsequent technological steps. Specifically, this type of locating marks is advantageously useful for carrying out certain subsequent technological steps, in particular, lithography steps. Furthermore, it is common for all the steps not to be carried out in one and the same production unit and for them to involve packaging and transport of structures that have undergone certain manufacturing steps to another site in order to carry out the following manufacturing steps with reference to the locating marks.

With reference to FIG. 8, the protective film is removed so as to free up the surface of the tiles. The structure is therefore ready for the subsequent manufacturing steps, for example, deposition or epitaxy of one or more additional layers on the tiles, the formation of electronic components in or on the tiles, etc. When the support substrate S is not the final support, the tiles may be transferred to a new support substrate, before or after the abovementioned manufacturing steps are carried out.

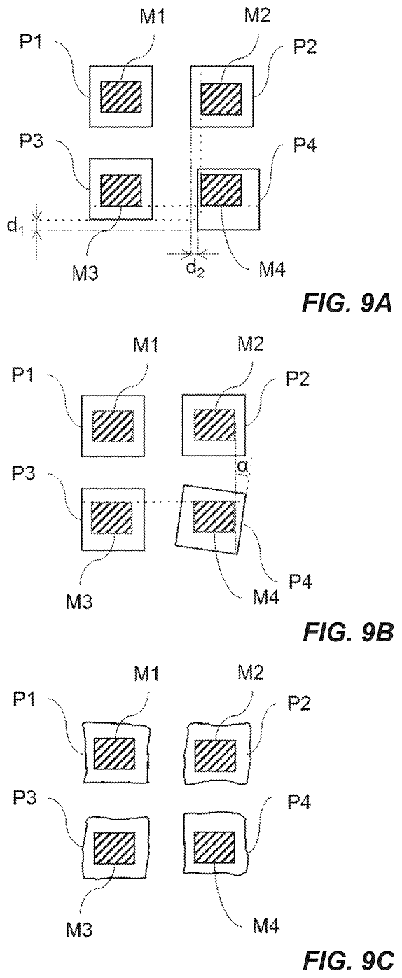

FIGS. 9A to 9C illustrate examples of correcting the geometry and/or distribution of the tiles.

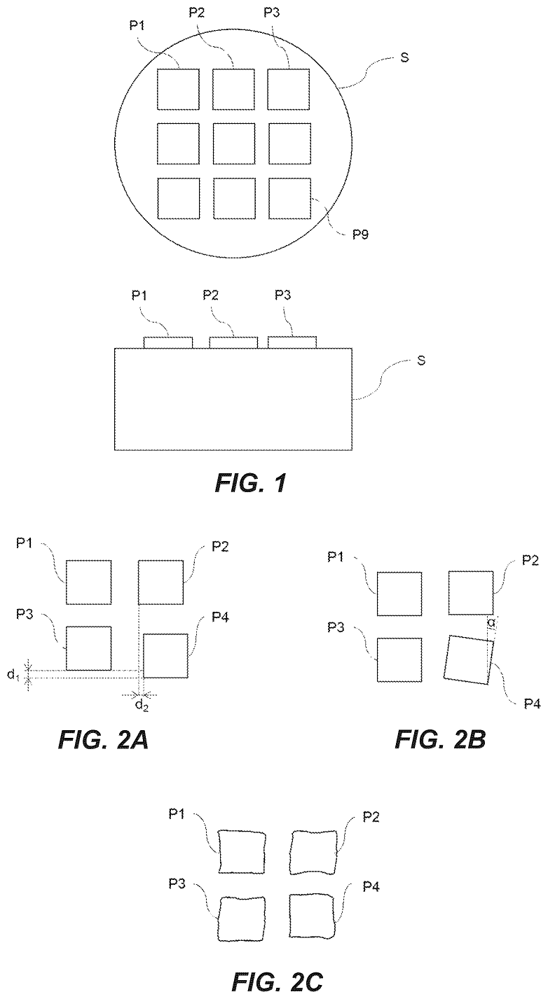

In the case of FIG. 9A, which corresponds to the error illustrated in FIG. 2A, the alignment error of the tile P4 with respect to the tiles P2 and P3 is corrected through the use of a mask of which the portions M2 and M4 are aligned horizontally and of which the portions M3 and M4 are aligned vertically. Consequently, following etching, the tiles in the portions M2, M3 and M4 of the protective film are perfectly aligned.

In the case of FIG. 9B, which corresponds to the error illustrated in FIG. 2B, the orientation error of the tile P4 with respect to the tiles P2 and P3 is corrected through the use of a mask of which the portions M2 and M4 are aligned horizontally and of which the portions M3 and M4 are aligned vertically, the portion of protective film M4 being inscribed in the geometry of the tile P4. Consequently, following etching, the tiles in the portions M2, M3 and M4 of the protective film are perfectly parallel and aligned.

In the case of FIG. 9C, which corresponds to the error illustrated in FIG. 2C, the edge irregularities of the tiles P1-P4 that are caused by the layer transfer have been corrected through the use of a mask of which the portions M1-M4 have a geometry in concordance with the desired geometry, each portion of protective film M1-M4 being inscribed in the geometry of the respective tile P1-P4.

As indicated above, the process according to the present disclosure may also be used to subdivide a tile into several smaller tiles. In this case, the geometry and/or distribution error may be considered to be incorrect simply because the number of tiles placed on the support substrate does not correspond to the expected number of tiles, even if the tiles are perfectly aligned.

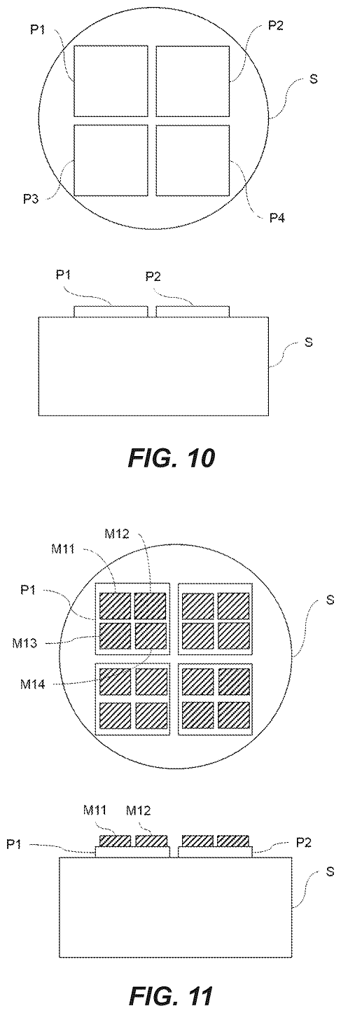

FIGS. 10 to 13 illustrate such an embodiment of the process.

As illustrated in FIG. 10, four tiles P1-P4 have been placed on a support substrate S. These tiles may have been placed directly from a donor substrate, for example, by means of the “Pick and Place” technique, or from a pseudo-donor substrate according to the process illustrated in FIGS. 4A-4E.

The tiles have relatively large dimensions, greater than the dimension necessary for producing the intended components. More specifically, each tile has a dimension greater than a multiple of the dimension of the tiles that is targeted in the manufacturing process. For example, each tile may have a dimension two or four times greater than the target dimension.

With reference to FIG. 11, a mask is formed, for example, by photolithography, on the tiles so as to define the desired pattern for the final tiles.

The mask comprises several portions of protective film on each tile. Thus, the tile P1 is covered with four portions M11, M12, M13, M14 of protective film, which are separated by an opening in the form of a cross.

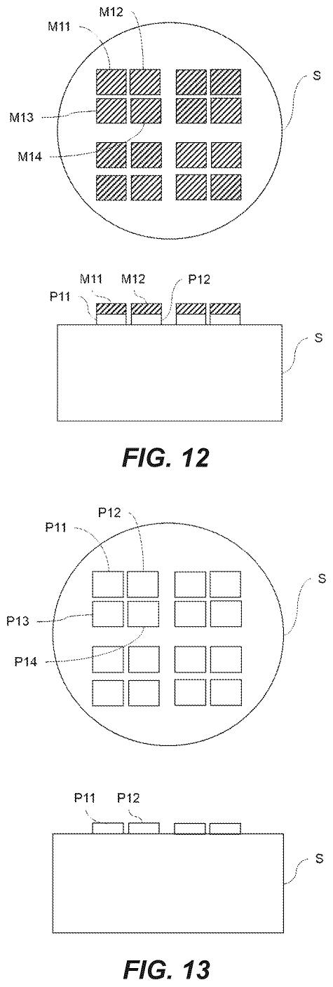

With reference to FIG. 12, the etching solution is applied to the structure in FIG. 11. Consequently, not only the periphery of the tiles is etched, but also the central part that is not covered by the protective film.

With reference to FIG. 13, the protective film is removed so as to free up the surface of the tiles.

At the end of etching, each tile (for example, the tile P1) has therefore been subdivided into four tiles (respectively, P11, P12, P13, P14).

In the example illustrated, the distance between the tile P1 and the adjacent tiles is greater than the distance between the tiles P11-P14 formed from the tile P1. However, it is, of course, possible to arrange the initial and final tiles so as to form a matrix of tiles having a perfectly regular geometry with an identical distance between the tiles obtained. Conversely, it is possible, by virtue of the mask and of the localized etching, to form a matrix of tiles having a complex geometry.

Compared with a process in which each tile P11-P14 has been placed individually on the support substrate S, for example, using the “Pick and Place” technique, the formation of the tiles P11-P14 according to the present disclosure is quicker because it involves only one step of placing the tile P1.

The process according to the present disclosure can be carried out directly on the tiles placed on the first support substrate or transferred to the second support substrate. However, particularly advantageously, when one or more additional layers are formed on the tiles, the process according to the present disclosure can be carried out after the formation of the additional layer or layers.

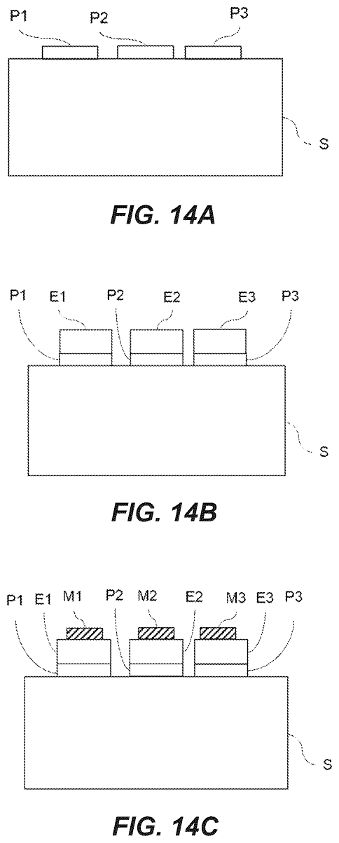

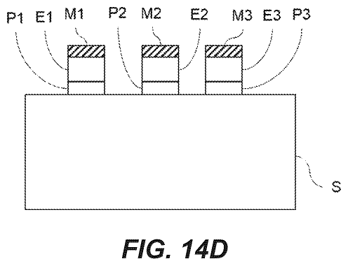

FIGS. 14A to 14D illustrate an embodiment of the process in which an epitaxial layer E1, E2, E3 (cf. FIG. 14B) has been formed on each tile P1, P2, P3 placed on the support substrate S (cf. FIG. 14). For example, the tiles are made of a monocrystalline material having a lattice parameter and a crystalline quality that are suitable for the epitaxial growth of the layers E1-E3. The layers E1-E3 may be made from the same material as the tiles, the epitaxial growth making it possible to thicken the tiles. Alternatively, the epitaxial layers E1-E3 may be made from a different material from that of the tiles, the epitaxial growth making it possible to form a composite stack.

As illustrated in FIG. 14C, the protective film M1, M2, M3 forming the mask is deposited on the surface of each epitaxial layer E1, E2, E3.

With reference to FIG. 14D, an etching solution suitable for attacking the material of the tiles and the material of the epitaxial layers is applied. At the end of etching, only the material of the tiles and of the epitaxial layers that is protected by the protective film remains.

The protective film can then be removed to free up the surface of the epitaxial layers and allow the continuation of the process for manufacturing electronic components in or on the tiles and epitaxial layers.

Thus, the present disclosure makes it possible to defer the adjustment of the geometry and alignment of the tiles to the most appropriate stage of the manufacturing process.

### Application Examples

The present disclosure presents different cases of particularly advantageous applications, in particular, in the field of microelectronics.

According to a first embodiment, the process may make it possible to correct the geometry and distribution of a plurality of tiles that have relatively large dimensions (that is to say having sides that are several millimeters long) and are spaced apart by several millimeters, placed on a support substrate with a diameter of 300 mm. The support substrate may be a silicon substrate or a substrate of the silicon on insulator (SOI) type.

In photonic applications, the active layer of the SOI may comprise a photonic circuit having passive or active devices, for example, one or more waveguides, one or more multiplexers, one or more micro-resonators, etc. The tiles transferred onto this layer may be made of InP, which is a material more suitable than silicon for the epitaxial growth of a stack of III-IV materials for forming a laser.

Given the relatively large size of the InP tiles, several circuits may optionally be created with each tile.

According to an alternative embodiment, the abovementioned tiles are subdivided into tiles of smaller dimensions by the process according to the present disclosure, each initial tile defining a cell comprising a plurality of chips that are each formed in a tile of small dimensions. It is thus possible to form on the support substrate two arrangement levels of tiles: a first level at the scale of the cells, which are arranged on the support substrate in a first pattern, and a second level at the scale of the chips, which are arranged within the respective cell in a second pattern.

In radiofrequency (RF) applications, the active layer of the SOI may comprise components that operate at relatively low frequency, while the tiles, which are advantageously made of InP or GaN, may comprise the components that operate at higher frequencies. For such applications, the size of the tiles, after correction of their alignment and/or geometry, may measure up to 1 cm of side length. The tiles are advantageously disposed densely on the support substrate, for example, with a distance between tiles, after correction of the alignment and/or geometry, that is typically less than 300 μm.

In micro-LED applications, the size of the GaN tiles, after correction of their alignment and/or geometry, is advantageously less than 50 μm.

1. A method of manufacturing a structure comprising at least two tiles on a substrate, the method comprising:
placing, on a support substrate, at least two tiles, the at least two tiles being arranged on the support substrate in an incorrect distribution and/or geometry relative to a target distribution and/or geometry;
forming a mask comprising a protective film partially covering the tiles, in a pattern defining the target distribution and/or geometry and at least one opening extending around the protective film; and
etching at least one tile through the opening in the mask so as to correct the arrangement of the tiles according to the target distribution and/or geometry.

2. The method of claim 1, wherein the pattern is defined in a system of coordinates of the at least two tiles.

3. The method of claim 1, wherein the pattern is defined in a system of coordinates of the support substrate.

4. The method of claim 1, further comprising placing the at least two tiles successively on the support substrate.

5. The method of claim 1, further comprising placing the at least two tiles simultaneously on the support substrate.

6. The method of claim 5, further comprising:
forming a pseudo-donor substrate by placing each tile of at least one donor substrate on a first support substrate;
bonding the pseudo-donor substrate to a second support substrate via the tiles; and
transferring a portion of the tiles to the second support substrate.

7. The method of claim 6, wherein the first support substrate and the second support substrate have identical diameters, greater than the diameter of the donor substrate.

8. The method of claim 6, further comprising bonding the pseudo-donor substrate to the second support substrate by molecular adhesion.

9. The method of claim 6, wherein transferring the portion of the tiles to the second support substrate comprises forming a weakened zone in each tile by implanting atomic species in each tile placed on the pseudo-donor substrate to define a portion to be transferred, bonding the pseudo-donor substrate to the second support substrate via the tiles, and detaching each tile along the weakened zone.

10. The method of claim 9, wherein each tile of the at least two tiles has a thickness of between 20 μm and 1000 μm, and the transferred portion of each tile has a thickness of between 30 nm and 1.5 μm.

11. The method of claim 6, wherein the forming of the mask and the etching of the at least one tile are carried out after each tile portion has been transferred to the second support substrate.

12. The method of claim 6, wherein the forming of the mask and the etching of the at least one tile are carried out on the tiles of the pseudo-donor substrate prior to bonding to the second support substrate.

13. The method of claim 6, wherein, to form the pseudo-donor substrate, each tile of the at least two tiles is placed in a cavity of the first support substrate.

14. The method of claim 1, wherein each tile of the at least two tiles has a side with a length less than or equal to 10 mm.

15. The method of claim 1, wherein each tile has a side with a length greater than or equal to 3 mm.

16. The method of claim 14, wherein the protective film covers each tile in at least two patterns separated by openings, and the etching of the tile through the openings in the mask forms at least two portions of tiles in the patterns from the tile.

17. The method of claim 1, wherein each tile of the at least two tiles comprises:
a semiconductor material, such as a III-V material, in particular, indium nitride, gallium nitride, aluminum nitride, indium arsenide, gallium arsenide, aluminum arsenide, indium phosphide, gallium phosphide or aluminum phosphide, or a IV or IV-IV material, in particular, germanium or silicon carbide;
a piezoelectric material, such as lithium tantalate, lithium niobate, potassium-sodium niobate, barium titanate, quartz, lead zirconate titanate, a compound of lead-magnesium niobate and of lead titanate, zinc oxide, aluminum nitride or aluminum-scandium nitride; and/or
an electrically insulating material, such as diamond, strontium titanate, yttria-stabilized zirconia or sapphire.

18. The method of claim 1, further comprising forming at least one epitaxial layer on each tile of the at least two tiles, the forming of the mask and the etching of the at least one tile being carried out after forming the at least one epitaxial layer.

19. The method of claim 10, wherein each tile has a thickness of between 100 μm and 700 μm.

20. The method of claim 14, wherein each tile of the at least two tiles has a side with a length less than or equal to 2 mm.
